(19) United States
(12) Patent Application Publication
(10) Pub. No.: US 2024/0013086 A1
(43) Pub. Date: Jan. 11, 2024

(54) SQUARE ARRAYS OF OCTAGONAL THREE-DIMENSIONAL MICROWAVE CAVITIES FOR QUANTUM COMPUTING

(71) Applicant: Nord Quantique inc., Sherbrooke (CA)

(72) Inventors: Dany LACHANCE-QUIRION, Sherbrooke (CA); Julien CAMIRAND LEMYRE, Sherbrooke (CA)

(21) Appl. No.: 18/201,476

(22) Filed: May 24, 2023

Related U.S. Application Data
(60) Provisional application No. 63/346,346, filed on May 27, 2022.

(51) Int. Cl. G06N 10/40

(52) U.S. Cl. CPC G06N 10/40

(57) ABSTRACT

Described are various embodiments of octagonal three-dimensional (3D) microwave cavities and square arrays thereof for quantum computing. In some embodiments, the system provides a plurality of 3D superconducting microwave cavities having an octagonal profile that allows nearest-neighbor coupling of the cavities according to a square tiling. This allows to build or assemble larger planar arrays of three-dimensional cavities in a modular fashion so as to increase the number of bosonic qubits in a space-efficient manner.

### CROSS-REFERENCE TO RELATED APPLICATIONS

This application claims priority to U.S. Provisional Patent Application No. 63/346,346, filed May 27, 2022, which is incorporated by reference in its entirety.

### FIELD OF INVENTION

The present disclosure relates to quantum computing systems, and, in particular, to square arrays of three-dimensional microwave cavities for quantum computing.

### BACKGROUND

Bosonic codes provide a promising route for hardware-efficient quantum computing when compared with traditional approaches using few-level systems as qubits. The larger number of levels in bosonic systems provides room for redundancy within a single physical system, enabling one to perform quantum error correction at the single-qubit level, something impossible with a two-level system qubit. Furthermore, the dominant source of noise in most physical implementations of harmonic oscillators is photon loss, a type of error for which bosonic codes can be made tolerant to first order.

Superconducting circuits is an important platform for bosonic codes due to the possibility of engineering desired interactions between an ancillary nonlinear resource (like a transmon, for example) necessary to encode, read out and correct the bosonic codes in high-quality harmonic modes of a microwave cavity. Indeed, without the ancillary nonlinear resource, only classical states can be created in harmonic oscillators using a coherent microwave source.

Three-dimensional superconducting microwave cavities are well-suited for bosonic codes with superconducting circuits due to their long lifetime routinely achieved (1-10 milliseconds to possibly longer) compared with state-of-the-art lifetimes achieved in two-dimensional circuits (10-100 microseconds). Given that the speed of the operations is in the same ballpark regardless of the dimensionality of the cavity, three-dimensional cavities therefore enable one to reduce the photon-loss error at the physical level by approximately at least two orders of magnitude, which in turns leads to a lower logical error rate.

However, despite the well establish potential of bosonic codes in three-dimensional superconducting circuits, there is currently no known architecture enabling planar lattices or arrays of three-dimensional cavities with integrated ancillary superconducting circuits and nearest-neighbor coupling. For example, simple square lattices have notable drawbacks when omitting squares to provide the required empty space, the boundary of the empty space has no edge in common with the cavities, making the integration of the ancillary resources much more difficult.

This background information is provided to reveal information believed by the applicant to be of possible relevance. No admission is necessarily intended, nor should be construed that any of the preceding information constitutes prior art or forms part of the general common knowledge in the relevant art.

### SUMMARY

The following presents a simplified summary of the general inventive concepts described herein to provide a basic understanding of some aspects of the disclosure. This summary is not an extensive overview of the disclosure. It is not intended to restrict key or critical elements of embodiments of the disclosure to delineate their scope beyond that which is explicitly or implicitly described by the following description and claims.

A need exists for a modular circuit quantum electrodynamics (cQED) element or device that allows to create planar arrays of coupled three-dimensional superconducting microwave cavities that can be tiled to increase the number of bosonic qubits thereof.

In accordance with a first aspect, there is provided a quantum computing device, the device comprising: a body having an outer octagonal profile associated with a first set of four lateral non-adjacent sides and a second set of four non-adjacent lateral sides; and a three-dimensional (3D) superconducting microwave cavity housed within said body configured to host and control said bosonic codes therein.

In one embodiment, the 3D superconducting microwave cavity is a coaxial-type cavity.

In one embodiment, the bosonic codes are selected from the group consisting of: cat codes, Gottesman-Kitaev-Preskill (GKP) codes, and binomial codes.

In one embodiment, the device comprises one or more ancilla resources operably coupled to said cavity via one side of said second set of non-adjacent lateral sides, and configured to control and measure cavity states hosted in said cavity.

In one embodiment, the one or more ancilla resources comprise a transmon qubit operably coupled to said cavity and a read-out resonator operably coupled to said transmon qubit.

In one embodiment, the ancilla resources are housed within a body portion protruding away laterally from one side of said second set of four non-adjacent lateral sides.

In one embodiment, the body portion and said body of said device are part of a same body.

In one embodiment, the cavity is coupled to a second cavity of a second device via a coupling device connected to one side of said first set of four non-adjacent lateral sides.

In one embodiment, the coupling device comprises at least one of: a transmon or a Superconducting Nonlinear Asymmetric Inductive eLement (SNAIL).

In one embodiment, the device further comprises: a driving hardware coupled to each cavity and said ancilla resources operable to generate and control said bosonic codes; and a measuring hardware coupled to each said one or more ancilla resources and configured to measure microwave signals associated with bosonic codes; and a controller operably coupled to said driving hardware and said measuring hardware and configured to control the operations of the driving hardware and measuring hardware so as to perform quantum computing operations on said bosonic codes.

In accordance with another aspect, there is provided a quantum computing system, the system comprising: a plurality of three-dimensional (3D) superconducting microwave cavities arranged in a square array configuration along a surface, each cavity configured to host therein bosonic codes and comprising a body having an outer octagonal profile associated with a first set of four lateral non-adjacent sides and a second set of four non-adjacent lateral sides.

In one embodiment, each of said 3D superconducting microwave cavity is a coaxial-type cavity.

In one embodiment, the bosonic codes are selected from the group consisting of: cat codes, Gottesman-Kitaev-Preskill (GKP) codes, and binomial codes.

In one embodiment, each 3D superconducting cavity is coupled to one or more ancilla resources.

In one embodiment, the one or more ancilla resources comprise a transmon qubit operably coupled to said cavity and a read-out resonator operably coupled to said transmon qubit.

In one embodiment, the one or more ancilla resources are coupled to the cavity via one side of said second set of four non-adjacent lateral sides.

In one embodiment, each 3D superconducting cavity is coupled to at least one nearest neighboring cavity of said square array via a coupling device connected to two facing sides of the first set of four non-adjacent lateral sides of the cavity and the nearest neighboring cavity, respectively.

In one embodiment, at least some of said 3D superconducting cavities are coupled to at least one second nearest cavity of said square array via a coupling device connected to two facing sides of said second set of four non-adjacent lateral sides of the cavity and the second nearest neighboring cavity, respectively.

In one embodiment, the coupling device comprises at least one of: a transmon or a Superconducting Nonlinear Asymmetric Inductive eLement (SNAIL).

In one embodiment, the one or more ancilla resources are not co-planar with respect to a surface the cavities are affixed on.

Other aspects, features and/or advantages will become apparent upon reading of the following non-restrictive description of specific embodiments thereof, given by way of example only with reference to the accompanying drawings.

### BRIEF DESCRIPTION OF THE DRAWINGS

Several embodiments of the present disclosure will be provided, by way of examples only, with reference to the appended drawings, wherein:

FIG. 1A is a schematic diagram of a square-octagonal tiling element geometry, in accordance with one embodiment;

FIG. 1B is a schematic diagram of a unit cell of planar coupled three-dimensional superconducting microwave cavities assembled according to the tiling element geometry of FIG. 1A, in accordance with one embodiment;

FIG. 1C is a schematic diagram of a larger array of three-dimensional superconducting microwave cavities assembled using the unit cell of FIG. 1B, in accordance with one embodiment;

FIG. 2 illustrates an aspect of the subject matter in accordance with one embodiment;

FIG. 3A is a perspective view of a superconducting device corresponding to the schematic diagram of FIG. 2, in accordance with one embodiment;

FIGS. 3B and 3C are cross-sectional perspective views of the superconducting device of FIG. 3A, in accordance with one embodiment;

FIGS. 3D, 3E and 3F illustrate a bottom view, a front view, and another perspective view, respectively, of the superconducting device of FIG. 3A, in accordance with one embodiment;

FIG. 4A is a schematic diagram of a quantum computing system comprising a planar array of the superconducting devices of FIG. 2, in accordance with one embodiment;

FIG. 4B is a front perspective view of a planar array of superconducting devices of FIGS. 3A-3F corresponding to the schematic diagram of FIG. 4A, in accordance with one embodiment;

FIG. 4C is a front view of the planar array of FIG. 4B, further showing the superconducting devices coupled to one another via a coupling device, in accordance with one embodiment;

FIG. 5 is a schematic diagram of another quantum computing system comprising a larger planar array of the superconducting devices of FIG. 2, in accordance with one embodiment;

FIG. 6A is a schematic diagram of a three-dimensional superconducting microwave cavity comprising two additional couplers coupled to the cavity via two opposite side walls, in accordance with one embodiment;

FIG. 6B is a schematic diagram illustrating another unit cell of planar coupled three-dimensional superconducting microwave cavities of FIG. 6A assembled according to the tiling element geometry of FIG. 1A wherein additional couplers are used to couple each cavity to two additional second-nearest neighboring cavities, in accordance with one embodiment; and

FIG. 6C is a schematic diagram illustrating an array of superconducting microwave cavities based on the unit cell of FIG. 6B, in accordance with one embodiment.

Elements in the several figures are illustrated for simplicity and clarity and have not necessarily been drawn to scale. For example, the dimensions of some of the elements in the figures may be emphasized relative to other elements for facilitating understanding of the various presently disclosed embodiments. Also, common, but well-understood elements that are useful or necessary in commercially feasible embodiments are often not depicted in order to facilitate a less obstructed view of these various embodiments of the present disclosure.

### DETAILED DESCRIPTION

Various implementations and aspects of the specification will be described with reference to details discussed below. The following description and drawings are illustrative of the specification and are not to be construed as limiting the specification. Numerous specific details are described to provide a thorough understanding of various implementations of the present specification. However, in certain instances, well-known or conventional details are not described in order to provide a concise discussion of implementations of the present specification.

Various apparatuses and processes will be described below to provide examples of implementations of the system disclosed herein. No implementation described below limits any claimed implementation and any claimed implementations may cover processes or apparatuses that differ from those described below. The claimed implementations are not limited to apparatuses or processes having all of the features of any one apparatus or process described below or to features common to multiple or all of the apparatuses or processes described below. It is possible that an apparatus or process described below is not an implementation of any claimed subject matter.

Furthermore, numerous specific details are set forth in order to provide a thorough understanding of the implementations described herein. However, it will be understood by those skilled in the relevant arts that the implementations described herein may be practiced without these specific details. In other instances, well-known methods, procedures and components have not been described in detail so as not to obscure the implementations described herein.

In this specification, elements may be described as “configured to” perform one or more functions or “configured for” such functions. In general, an element that is configured to perform or configured for performing a function is enabled to perform the function, or is suitable for performing the function, or is adapted to perform the function, or is operable to perform the function, or is otherwise capable of performing the function.

It is understood that for the purpose of this specification, language of “at least one of X, Y, and Z” and “one or more of X, Y and Z” may be construed as X only, Y only, Z only, or any combination of two or more items X, Y, and Z. (e.g., XYZ, XY, YZ, ZZ, and the like). Similar logic may be applied for two or more items in any occurrence of “at least one . . . ” and “one or more . . . ” language.

The systems and methods described herein provide, in accordance with different embodiments, different examples of a modular circuit quantum electrodynamics (cQED) quantum computing system. In some embodiments, the system provides a plurality of three-dimensional superconducting microwave cavities having a novel octagonal profile that allows nearest-neighbor coupling of the cavities according to a square tiling. This allows to build or assemble larger planar arrays of three-dimensional cavities in a modular fashion so as to increase the number of bosonic qubits in a space-efficient manner.

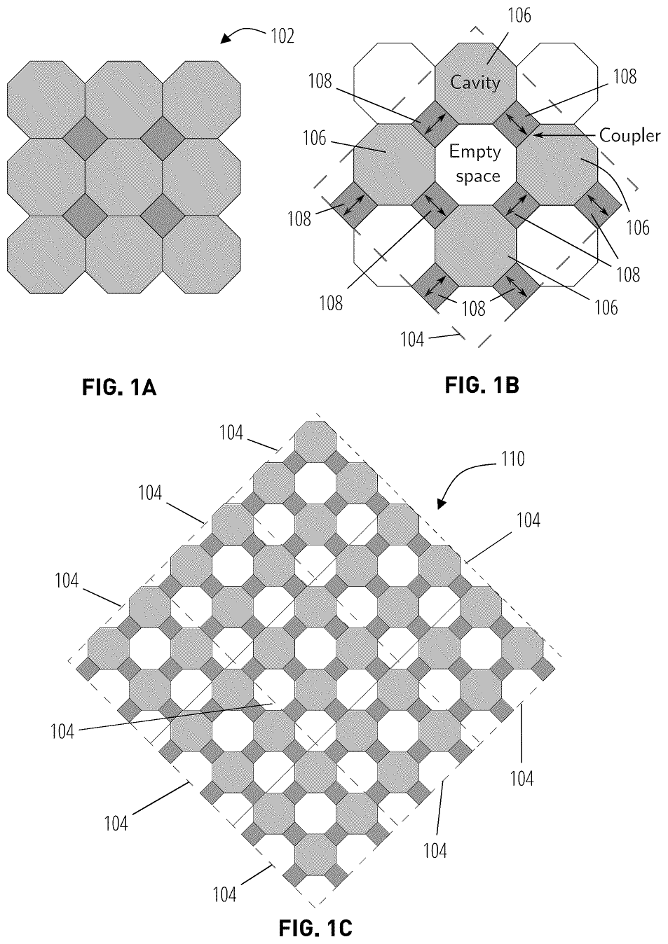

FIG. 1A illustrates schematically, in accordance with one embodiment, a square-octagonal tiling element geometry or architecture, generally referred using the numeral 102. In this example, the tiling element geometry 102 comprises, as the name implies, a combination of multiple (here 9 as an example) octagonally-shaped elements or octagons, each in contact with its neighboring octagon via non-adjacent edges in a square tiling arrangement. FIG. 1A further shows that the empty space created by the assembled octagons is filled with square elements (here four). This tiling arrangement or architecture 102 can be leveraged or used to implement modular quantum computing systems as will be discussed herein.

FIG. 1B shows schematically an example of a square-octagonal tiling element geometry 102 adapted to implement a “unit cell” 104 of coupled three-dimensional superconducting microwave cavities. In this example, a plurality of planar three-dimensional superconducting microwave cavities 106 are designed or shaped to have an octagonal footprint or profile so as to occupy non-adjacent octagonally-shaped elements. In addition, they are configured to be coupled to a neighbouring cavity through couplers or coupling devices 108 having a square footprint or profile so as to fit within the square-shaped elements. The remaining non-adjacent octagonally-shaped elements are omitted to provide free-space for ancilla resources and cabling.

In FIG. 1B, the dashed line represents an example of a “unit cell” 104 of cavities which can be tiled or coupled in a square planar tiling configuration to create a larger array, as shown in FIG. 1C. Thus, in some embodiments, base units of planar three-dimensional superconducting microwave cavities arrays arranged in the unit cell 104 of FIG. 1B may be constructed or provided. These may in turn be coupled together to create a larger planar array 110, for example as shown in FIG. 1C. Thus, the number of bosonic qubits of a quantum computing system can be increased in a space-efficient manner.

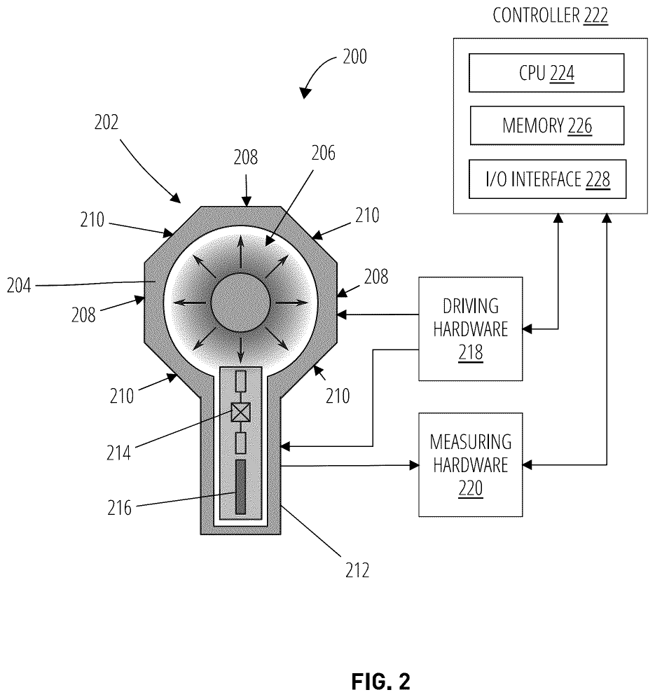

FIG. 2 illustrates schematically a top view of an exemplary cQED device 200, in accordance with one embodiment, that comprises a 3D superconducting microwave cavity 202. The cavity 202 comprises a casing or housing 204 having an octagonal profile that can be used to implement planar lattices or arrays thereof as discussed above in relation to FIGS. 1A to 1C. The superconducting cavity 202 is a three-dimensional seamless coaxial-type superconducting microwave cavity configured to house and sustain therein long-lived microwave modes 206 using a rotation-symmetric electric field (for example as described in M. Reagor, PhD thesis, Yale University 2015, which is incorporated by reference herein in its entirety). The three-dimensional superconducting microwave cavity 202 is configured or operable to host and maintain therein a plurality of long-lived bosonic codes or qubit, such as Gottesman-Kitaev-Preskill (GKP) qubit. However, other bosonic codes or qubits known in the art may also be used or implemented by the cavity 202, for example cat qubits or binomial qubits or others.

The three-dimensional superconducting microwave cavity 202 is advantageously designed to have a casing or body 204 comprising eight external vertical side walls as shown. These walls are divided into two sets of non-adjacent side walls 208 and 210. Thus, one set of non-adjacent sides walls 210 may be used to couple the cavity 202 to up to four other cavities. Of the other four side walls 208, one is used to couple ancilla resources 212 to the cavity 202. In some embodiments, the ancilla resources 212 may comprise an ancillary transmon 214 and linear readout resonator 216. The readout resonator 216 is dispersively coupled to the transmon 214 and may be used, at least in part, to control and read the transmon state. Different types of resonators known in the art may be considered, including for example one or more Purcell filtered resonators. The skilled person in the art will appreciate that different techniques or implementations of an ancilla resources is known in the art that the illustrated device is used as an example only. As shown schematically in FIG. 2, the presence of the elongated rectangular casing or housing of the ancilla resources 212 protruding from the cavity 202 makes it physically difficult to efficiently couple a plurality of such superconducting circuit devices 200 to one another in a space-efficient manner, for example using a square tiling.

The driving hardware 218 typically comprises one or more microwave generators and an arbitrary waveform generator (AWG) or other configured to generate coherent microwave drives and pulses. These may be used for example to prepare or initialize the transmon in a given state using control pulses. The one or more generators are typically coupled via one or more transmission lines to the cavity 202 using for example a cavity control port (not shown) and to the ancilla resources 212—and thus the transmon 214 and the resonator 216—using for example an ancilla control port (not shown).

The measuring hardware 220 is used to read out the state of the transmon 214. Thus, the measuring hardware 220 typically comprises one or more digitizers configured to detect and measure microwave signals or tones scattered off the read-out resonator 216 via a readout port (not shown). The skilled person in the art will understand that different hardware variations and/or techniques may be used to perform the qubit readout, without limitation. It will also be understood that conventional or typical hardware components, such as amplifiers, band-pass filters, up or down converters, analog-to-digital converters (ADC), or others, may also be included in the driving hardware 218 and the measuring hardware 220, without limitations.

Both the driving hardware 218 and the measuring hardware 220 are coupled to a controller 222. The controller 222 is typically provided in the form of a classical computer, which comprises one or more classical processors 224 coupled to a memory 226 and a input/output interface 228. The controller 222 is used to operate the driving hardware 218 and the measuring hardware 220 so as to set, control and measure quantum states in the device 200 to implement therewith bosonic codes or qubits, and control logical operations therewith.

In addition, not illustrated in FIG. 2 is a well-known cooling hardware used to maintain the superconducting components, namely the superconducting cavity 202 and the transmon 214, at near-zero Kelvin temperatures. Different means of cooling these components at near-zero Kelvin temperatures well known in the art may be used, without limitations. In contrast, the driving hardware 218, measuring hardware 220 and controller 222, or at least parts thereof, are typically operated at various higher temperatures.

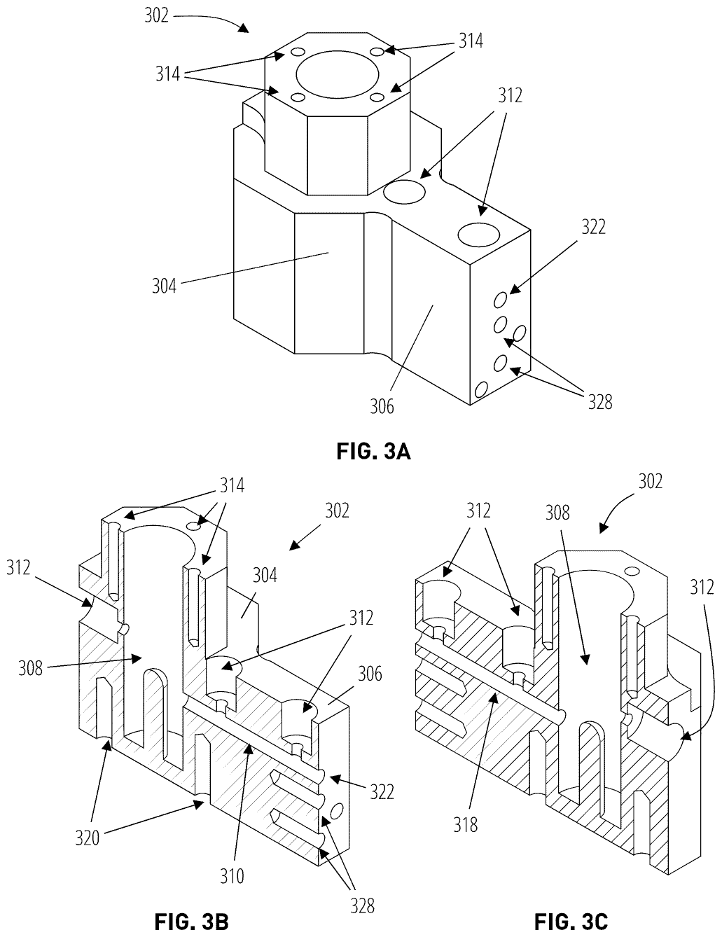

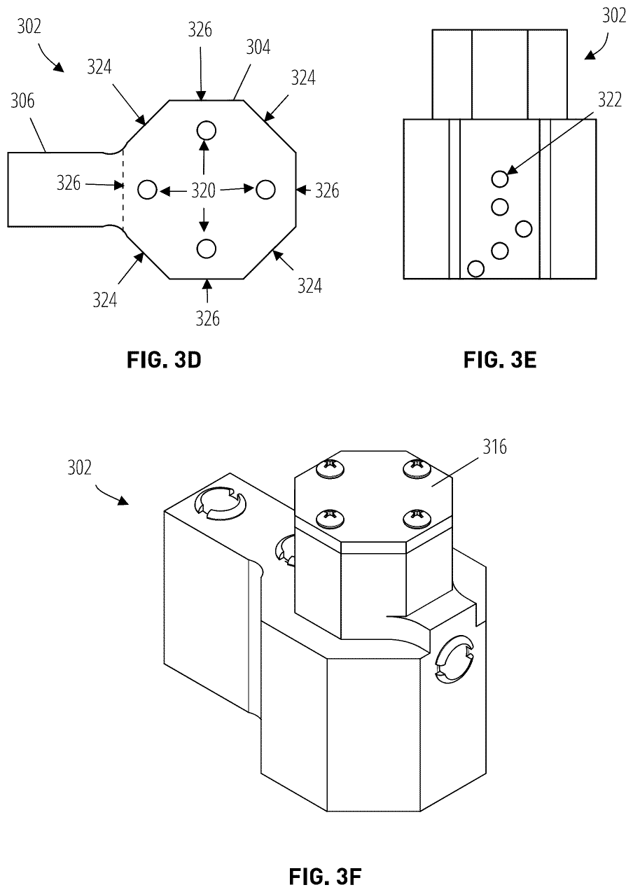

FIG. 3A is a perspective view of an exemplary superconducting device 302 comprising a three-dimensional superconducting microwave cavity body 304 and its ancilla resources body portion 306 corresponding to the octagonal profile discussed in FIG. 2. FIGS. 3B and 3C show corresponding cross-sectional side views of the device 302 showing the co-axial design of the interior of the cavity 308 and the waveguide 310 location in the ancilla resources body portion 306. The locations of the readout and control ports 312 is also shown.

FIGS. 3D and 3E show a bottom view and a front view of the device 302, in accordance with one embodiment. FIG. 3F is another perspective view wherein the device 302 further comprises a cover 316 for sealing the top opening of the cavity 308. Multiple fastening holes 314, 320 and 328 are also shown. These are used to fasten a cover to the cavity 308 (314), attach or fasten the device 302 to a surface (320) and affix the ancilla resources component that is inserted into the waveguide 310 via the opening 322 (328).

In the example of FIGS. 3A-3F, the superconducting device 302 is configured so as to have at least the inner surface of the cavity 308 and the waveguide 310 made of a superconducting material. In some embodiments, the whole body of the device 302 (e.g., body 304 and body portion 306) may be manufactured from a superconducting material, for example a high-purity aluminum. Other embodiments may use different superconducting materials known in the art, for example, niobium, tantalum or the like, alone or in combination. In some embodiments, the body may be manufactured from a non-superconducting material, but have the inner surface of the cavity 308 and waveguide 310 coated or covered by a superconducting material such that it retains the ability to host and control superconducting qubits therein.

While the illustrated examples of FIGS. 3A-3F have the superconducting cavity 304 and the ancilla resources 306 part of a same body, housing or casing, other embodiments may readily have the casing or housing of the ancilla resource body portion 306 releasably attachable to the 3D cavity body 304. In addition, FIGS. 3A-3E also show the various fastening holes 314

In some embodiments, one or more lateral walls/sides of the body 304 may be coupled to a coupler device. In some embodiments, this may be realized, for example, by providing a waveguide tunnel extending radially from the cavity 308 to the sides or side walls, as will be understood by the skilled person in the art. FIG. 3C illustrates the first set of non-adjacent lateral sides 328 (used mainly for coupling multiple devices 302 in a square array configuration), and the second set of non-adjacent lateral sides 330 (one side typically used to couple the ancilla resources—via the body portion 306, but other sides may also be used for coupling to second nearest neighbors, as will be further discussed below).

The skilled person in the art will appreciate that the external lateral shape or profile of the body 304 may not be perfectly octagonal but may be partially or completely rounded instead, as long as the octagonal symmetry is retained when connecting the couplers or coupling devices by the connection to the coupling devices.

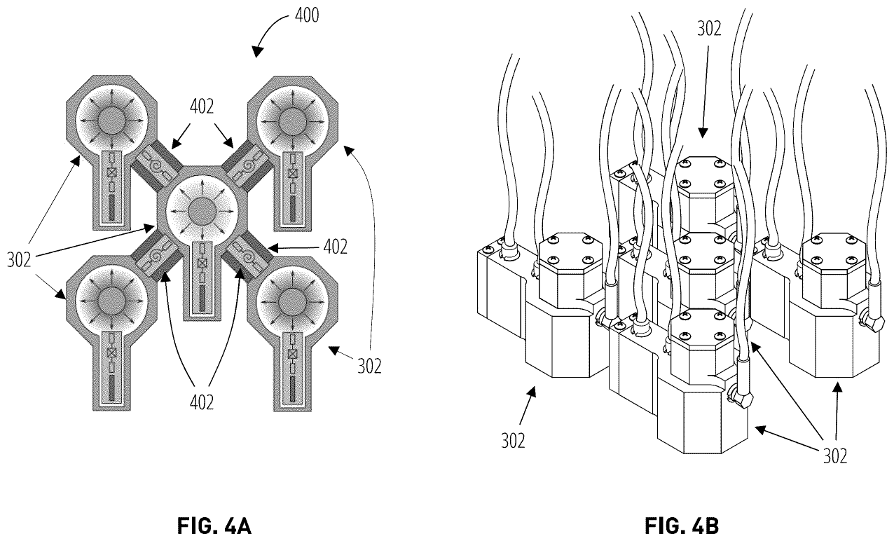

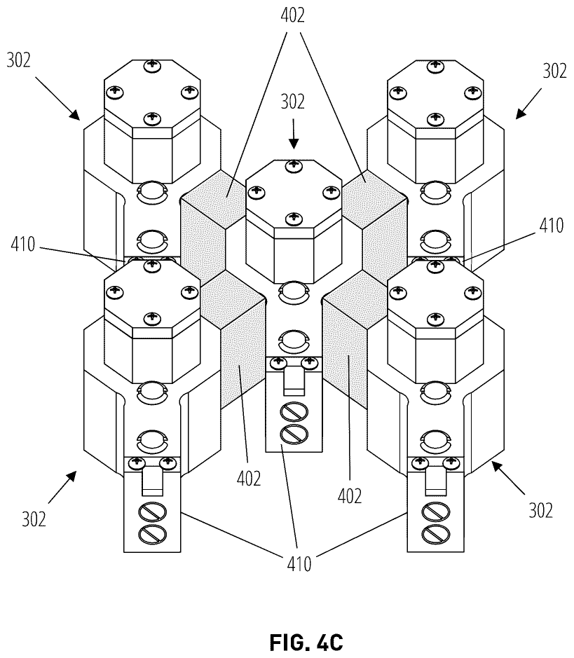

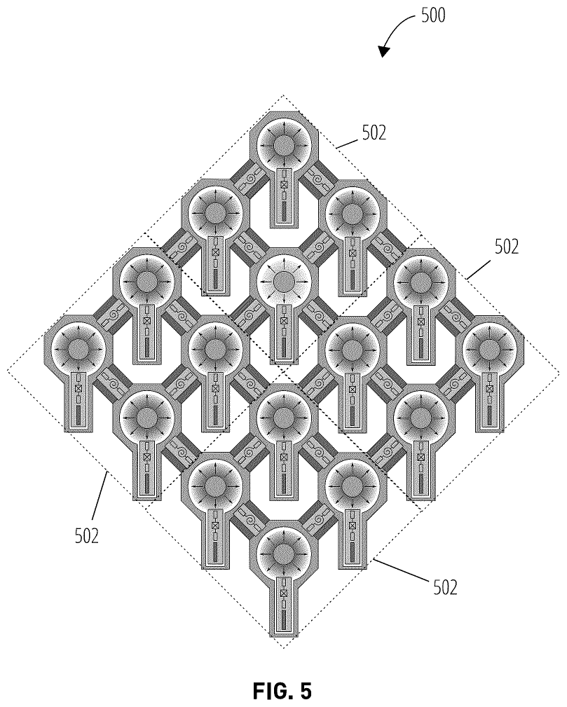

FIG. 4A provides an exemplary schematics top view of network or array 400 of coupled superconducting devices 402 arranged in a planar fashion corresponding to the tiling element geometry discussed above, in accordance with one embodiment. In this example, the central cavity is shown being quantum mechanically coupled via couplers or coupling devices 404 to the four neighboring superconducting devices. It can be clearly seen that the architecture or geometry is advantageously tailored to allow enough space for the ancilla resources and for the couplers, while allowing a dense coupling where the central cavity can be coupled to up to four neighboring cavities, via the four side surfaces 210 shown in FIG. 2. Furthermore, as indicated schematically, in this example, each coupler or coupling device 404 comprises a Superconducting Nonlinear Asymmetric Inductive eLement (SNAIL). However, the skilled person in the art will appreciate that other coupling means other than a SNAIL may be used, for example a simple transmon or the like.

FIG. 4B shows a perspective view of an exemplary quantum computing system comprising a planar array 406 comprising five superconducting devices 302 arranged according the schematic diagram of FIG. 4A. Also shown are the various cables connected to the readout and control ports. The skilled person in the art will understand that in FIG. 4B, the array 406 is shown without couplers for clarity only.

FIG. 4C is a front view of the array 406 here shown with the coupling devices 402 coupling the devices 302. The coupling devices 402 are configured to couple the cavities of two adjacent devices 302 by connecting two sides facing each other, one from each device, of a set of non-adjacent lateral sides 328 (as illustrated in FIG. 3D) thereby forming a square array. Also shown in FIGS. 4B and 4C is the head of the ancilla resources component 412 comprising the transmon 214 and readout resonator 216 housed within the waveguide 310 (inserted via the opening 322 of FIG. 3A). In some embodiments, the component 412 may be made of a good thermally conducting material, such as copper, and the transmon 214 and resonator 216 may be provided in the form a chip or the like, and shaped to be removably engaged within the waveguide 310 as will be familiar to the skilled person in the art.

FIG. 5 is a schematic diagram illustrating a larger planar array or quantum computing system 500 comprising 16 of the devices 200 of FIG. 2. This figure clearly illustrates how each “tile” 502 of four coupled devices 200 can be reproduced to create a larger array. It will be understood that the couplers have been omitted on the edge devices, as couplers at these locations are not required. It will be understood that the driving hardware, measuring hardware and controller have been omitted in FIGS. 4A-4B and FIG. 5 only so as to provide a less obstructed view of the arrays 400 and 500, for example.

It will be understood that in some embodiments, each device 200 may comprise its own driving hardware 218 and measuring hardware 220, while other embodiments may share, at least in part, a same driving hardware and/or measuring hardware along multiple devices in the array, via multiplexing or other techniques. The skilled person in the art will appreciate that multiple techniques for controlling and reading from the cavities in a given array may be used, without restriction. Furthermore, in some embodiments, a single controller may be coupled to each cavity 200 in an array so as to operate the array of devices 200 as a single quantum computing system, and so as to execute quantum computing algorithms therewith.

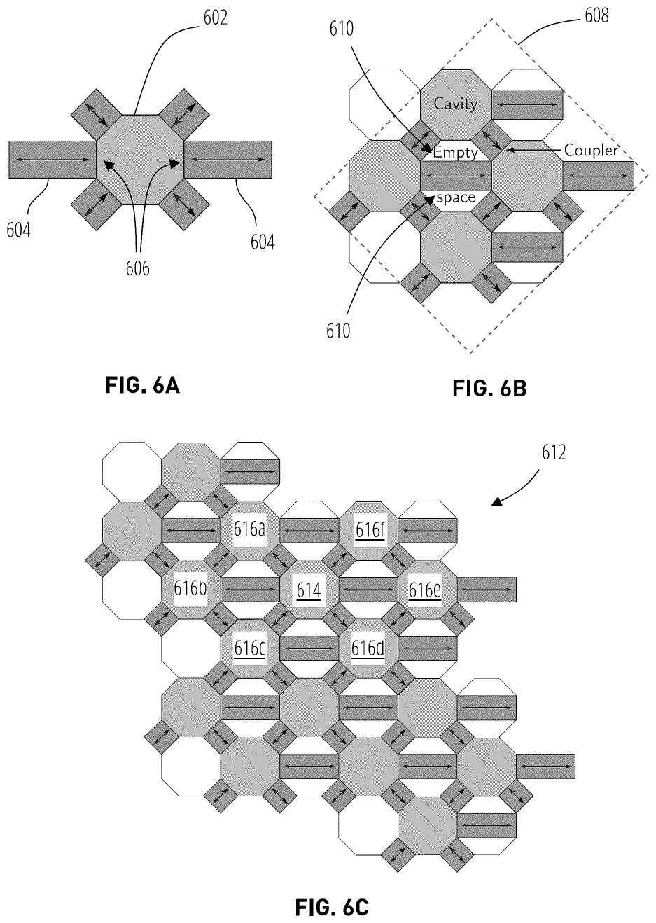

In some embodiments, a cQED device comprising a 3D superconducting microwave cavity having an octagonal profile may have the one or more ancilla resources reduced in size, integrated (at least in part) within the cavity housing and/or located in a non-co-planar location so as to allow for denser arrays with additional couplings. For example, as illustrated in FIG. 6A, an exemplary cavity 602 (shown without the ancilla resources for clarity only) is shown comprising two additional couplers 604 coupled to the cavity 602 via two opposite side walls 606. FIG. 6B shows a “unit cell” 608 of octagonal 3D superconducting microwave cavities using the additional couplers. The additional couplers 604 are configured to couple each cavity to two opposite second nearest neighbors in the array. It will be understood that the ancilla resources (not shown) can be either located in a non-co-planar location or are small enough so as to fit into the empty space 610 between the cavities. This unit cell may be used to create even larger arrays, for example the array 612 of FIG. 6C, where it is shown that each cavity in the array 612, for example cavity 614, can be coupled to at most six other cavities (for example cavities 616a-f).

It will be understood that the expression classical or conventional “computer”, or “controller”, as used herein is not to be interpreted in a limiting manner. “computer” is rather used in a broad sense to generally refer to the combination of some form of one or more processing units and some form of memory system accessible by the processing unit(s). “Controller” is used in a broad sense to generally refer to a device which performs a function of controlling, and may be a computer or another type of device. The memory system if a computer can be of the non-transitory type. The use of the expression “computer” in its singular form as used herein includes within its scope the combination of a two or more computers working collaboratively to perform a given function, independently of whether these two or more computers are local, remote, or distributed. Moreover, the expression “computer” as used herein includes within its scope the use of partial capabilities of a given processing unit.

A processing unit can be embodied in the form of a general-purpose micro-processor or microcontroller, a digital signal processing (DSP) processor, an integrated circuit, a field programmable gate array (FPGA), a reconfigurable processor, a programmable read-only memory (PROM), to name a few examples. The memory system can include a suitable combination of any suitable type of computer-readable memory located either internally, externally, and accessible by the processor in a wired or wireless manner, either directly or over a network such as the Internet.

A computer-readable memory can be embodied in the form of random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM) to name a few examples.

A computer can have one or more input/output (I/O) interface to allow communication with a human user and/or with another computer via an associated input, output, or input/output device such as a keyboard, a mouse, a touchscreen, an antenna, a port, etc. Each I/O interface can enable the computer to communicate and/or exchange data with other components, to access and connect to network resources, to serve applications, and/or perform other computing applications by connecting to a network (or multiple networks) capable of carrying data including the Internet, Ethernet, plain old telephone service (POTS) line, public switch telephone network (PSTN), integrated services digital network (ISDN), digital subscriber line (DSL), coaxial cable, fiber optics, satellite, mobile, wireless (e.g. Wi-Fi, Bluetooth, WiMAX), SS7 signaling network, fixed line, local area network, wide area network, to name a few examples.

It will be understood that a computer can perform functions or processes via hardware or a combination of both hardware and software. For example, hardware can include logic gates included as part of a silicon chip of a processor. Software (e.g., application, process) can be in the form of data such as computer-readable instructions stored in a non-transitory computer-readable memory accessible by one or more processing units. With respect to a computer or a processing unit, the expression “configured to” relates to the presence of hardware or a combination of hardware and software which is operable to perform the associated functions.

While the present disclosure describes various embodiments for illustrative purposes, such description is not intended to be limited to such embodiments. On the contrary, the applicant's teachings described and illustrated herein encompass various alternatives, modifications, and equivalents, without departing from the embodiments, the general scope of which is defined in the appended claims. Except to the extent necessary or inherent in the processes themselves, no particular order to steps or stages of methods or processes described in this disclosure is intended or implied. In many cases the order of process steps may be varied without changing the purpose, effect, or import of the methods described.

Information as herein shown and described in detail is fully capable of attaining the above-described object of the present disclosure, the presently preferred embodiment of the present disclosure, and is, thus, representative of the subject matter which is broadly contemplated by the present disclosure. The scope of the present disclosure fully encompasses other embodiments which may become apparent to those skilled in the art, and is to be limited, accordingly, by nothing other than the appended claims, wherein any reference to an element being made in the singular is not intended to mean “one and only one” unless explicitly so stated, but rather “one or more.” All structural and functional equivalents to the elements of the above-described preferred embodiment and additional embodiments as regarded by those of ordinary skill in the art are intended to be encompassed by the present claims. Moreover, no requirement exists for a system or method to address each and every problem sought to be resolved by the present disclosure, for such to be encompassed by the present claims. Furthermore, no element, component, or method step in the present disclosure is intended to be dedicated to the public regardless of whether the element, component, or method step is explicitly recited in the claims. However, that various changes and modifications in form, material, work-piece, and fabrication material detail may be made, without departing from the spirit and scope of the present disclosure, as set forth in the appended claims, as may be apparent to those of ordinary skill in the art, are also encompassed by the disclosure.

What is claimed is:

1. A quantum computing device, the device comprising:
a body having an outer octagonal profile associated with a first set of four lateral non-adjacent sides and a second set of four non-adjacent lateral sides; and
a three-dimensional (3D) superconducting microwave cavity housed within said body configured to host and control said bosonic codes therein.

2. The device of claim 1, wherein said 3D superconducting microwave cavity is a coaxial-type cavity.

3. The device of claim 1, wherein said bosonic codes are selected from the group consisting of: cat codes, Gottesman-Kitaev-Preskill (GKP) codes, and binomial codes.

4. The device of claim 1, further comprising one or more ancilla resources operably coupled to said cavity via one side of said second set of non-adjacent lateral sides, and configured to control and measure cavity states hosted in said cavity.

5. The device of claim 4, the one or more ancilla resources comprise a transmon qubit operably coupled to said cavity and a read-out resonator operably coupled to said transmon qubit.

6. The device of claim 4, wherein the ancilla resources are housed within a body portion protruding away laterally from one side of said second set of four non-adjacent lateral sides.

7. The device of claim 6, wherein the body portion and said body of said device are part of a same body.

8. The device of claim 1, wherein the cavity is coupled to a second cavity of a second device via a coupling device connected to one side of said first set of four non-adjacent lateral sides.

9. The device of claim 8, wherein said coupling device comprises at least one of: a transmon or a Superconducting Nonlinear Asymmetric Inductive eLement (SNAIL).

10. The device of claim 4, further comprising:
a driving hardware coupled to each cavity and said ancilla resources operable to generate and control said bosonic codes; and
a measuring hardware coupled to each said one or more ancilla resources and configured to measure microwave signals associated with bosonic codes; and
a controller operably coupled to said driving hardware and said measuring hardware and configured to control the operations of the driving hardware and measuring hardware so as to perform quantum computing operations on said bosonic codes.

11. A quantum computing system, the system comprising:
a plurality of three-dimensional (3D) superconducting microwave cavities arranged in a square array configuration along a surface, each cavity configured to host therein bosonic codes and comprising:
a body having an outer octagonal profile associated with a first set of four lateral non-adjacent sides and a second set of four non-adjacent lateral sides.

12. The system of claim 11, wherein each of said 3D superconducting microwave cavity is a coaxial-type cavity.

13. The system of claim 12, wherein said bosonic codes are selected from the group consisting of: cat codes, Gottesman-Kitaev-Preskill (GKP) codes, and binomial codes.

14. The system of claim 11, wherein each 3D superconducting cavity is coupled to one or more ancilla resources.

15. The system of claim 14, wherein said one or more ancilla resources comprise a transmon qubit operably coupled to said cavity and a read-out resonator operably coupled to said transmon qubit.

16. The system of claim 15, wherein said one or more ancilla resources are coupled to the cavity via one side of said second set of four non-adjacent lateral sides.

17. The system of claim 14, wherein each 3D superconducting cavity is coupled to at least one nearest neighboring cavity of said square array via a coupling device connected to two facing sides of the first set of four non-adjacent lateral sides of the cavity and the nearest neighboring cavity respectively.

18. The system of claim 17, wherein at least some of said 3D superconducting cavities are coupled to at least one second nearest cavity of said square array via a coupling device connected to two facing sides of said second set of four non-adjacent lateral sides of the cavity and the second nearest neighboring cavity, respectively.

19. The system of claim 17, wherein said coupling device comprises at least one of: a transmon or a Superconducting Nonlinear Asymmetric Inductive eLement (SNAIL).

20. The system of claim 14, wherein the one or more ancilla resources are not co-planar with respect to a surface the cavities are affixed on.
